(19) United States
(12) Patent Application Publication
(10) Pub. No.: US 2007/0298520 A1
(43) Pub. Date: Dec. 27, 2007

(54) Method of Producing an Element Comprising an Electrical Conductor Encircled By Magnetic Material

(76) Inventors: Philippe Renaud, Tournefeuille (FR); Frederic Dumestre, Goudon (FR); Catherine Amiens, Toulouse (FR); Bruno Chaudret, Vigloule-Auzil (FR)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/596,370

(22) PCT Filed: Dec. 10, 2004
(86) PCT No.: PCT/EP04/14167

§ 371 Date: Mar. 22, 2007

(30) Foreign Application Priority Data
Dec. 10, 2003 (EP) 03293095.0

(51) Int. Cl. H01L 21/00

(52) U.S. Cl. 438/3; 257/E21.001

(57) ABSTRACT

A method of producing an electrical inductor circuit element comprising an elongate electrical conductor encircled by magnetic material extending along at least a part of the conductor. First and second sacrificial layers are formed across the conductor respectively above and below the conductor, at least parts of the sacrificial layers are removed to leave a space encircling the conductor, a fluid comprising magnetic nanoparticles dispersed in a liquid dispersant is introduced into the space, and the dispersant is removed leaving the magnetic nanoparticles densely packed in the space as at least part of the magnetic material.

### FIELD OF THE INVENTION

This invention relates to a method of producing an electrical circuit element, and more particularly an element comprising an elongate electrical conductor encircled by magnetic material extending along at least a part of the conductor.

### BACKGROUND OF THE INVENTION

Encircling the conductor of an inductive element with a magnetic material can significantly increase its inductance or reduce its size while maintaining a constant inductance. A reduction in inductor size is especially valuable for microscopic inductors made using semiconductor-type manufacturing techniques such as mask-controlled deposition and etching of materials on a substrate, since it leads to a reduction in occupied chip area which enables more devices to be produced for a given sequence of manufacturing operations and a given overall substrate (‘wafer’) size.

However using even high resistivity ferromagnetic materials restricts the applicability of such devices to well below 1 GHz due to ferromagnetic resonance (FMR) losses. A composite made of electrically isolated ferromagnetic nanoparticles that coats a metal wire (especially a straight line or meander) in such a way that the easy axis magnetization is set along the wire axis would help increase the FMR frequency and enable full advantage to be taken of having the magnetic field normal to the easy axis, hence having maximum RF magnetic response from the composite.

Magnetic shielding is another property for which it is desirable to encircle an electrical conductor with magnetic material extending along at least a part of the conductor. The magnetic flux round the conductor generated by current flowing along the conductor is contained to a large extent by the encircling magnetic material instead of radiating out and causing electromagnetic interference. This can be especially useful in applications where an inductor is disposed in proximity to other components that are sensitive to parasitic electromagnetic fields.

Process solutions for the fabrication of such embedded conductor structures are needed. U.S. Pat. No. 6,254,662 discloses forming a thin film of magnetic alloy nanoparticles for high density data storage. However, no disclosure is made of a method of producing an inductive element comprising an elongate conductor encircled by magnetic material extending along at least a part of the conductor.

### SUMMARY OF THE INVENTION

The present invention provides a method of producing an electrical circuit element as described in the accompanying claims.

### BRIEF DESCRIPTION OF THE DRAWINGS

FIG. 1 is a diagrammatic sectional view of an inductive circuit element produced by a method in accordance with one embodiment of the invention, given by way of example,

FIG. 2 is a diagrammatic scrap perspective view of magnetic material in the inductive circuit element of FIG. 1,

FIG. 3 is a graph of typical ferromagnetic resonance frequencies as a function of aspect ratio for different shaped particles in the magnetic material,

FIG. 4 shows cross-sections through part of the inductive circuit element during successive steps in its production by a method in accordance with one embodiment of the invention, given by way of example,

FIG. 5 shows cross-sections through part of the inductive circuit element during successive steps in its production by a method in accordance with another embodiment of the invention, given by way of example,

FIG. 6 shows a plan view and a cross-section through the part of the inductive circuit element after the production steps of FIG. 4 or FIG. 5,

FIG. 7 is a cross-section through the part of the inductive circuit element after a further step in the method of production following the steps of FIG. 4 or FIG. 5, and

FIG. 8 is a cross-section through the part of the inductive circuit element after a further step in the method of production following the steps of FIG. 4 or FIG. 5.

### DETAILED DESCRIPTION OF THE PREFERRED EMBODIMENTS

The manufacturing process illustrated in the accompanying drawings is one embodiment of a method of producing an electrical circuit element comprising an elongated electrical conductor 1 encircled by a coating of magnetic material 2 of high permeability that extends along at least a substantial part of the conductor 1. This fabrication method for coated metal wires with magnetic composite is applicable for inductors that are capable of functioning well into the GHz frequency range, potentially as high as 10 GHz.

In one embodiment of the process, the magnetic material 2 is in intimate contact with the conductor 1. In another embodiment of the process, the conductor is embedded in the magnetic material 2 without being fully in intimate contact with it. Coating the electrical conductor 1 of an inductor in this way with high permeability magnetic material in a thin layer substantially increases the inductance of the circuit element. As shown in FIG. 2, where the magnetic coating for three adjacent parallel conductor elements of a meander device is shown in three dimensions, the conductors 1 themselves being omitted so as to show the direction of current flow by a dot for current directed into the plane of the drawing and an X for current coming out of the plane of the drawing, in each case the magnetic flux generated by the current is directed circularly around the length of the conductor and therefore is contained in the magnetic coating 2 encircling the conductor, provided that the coating 2 is not too thin.

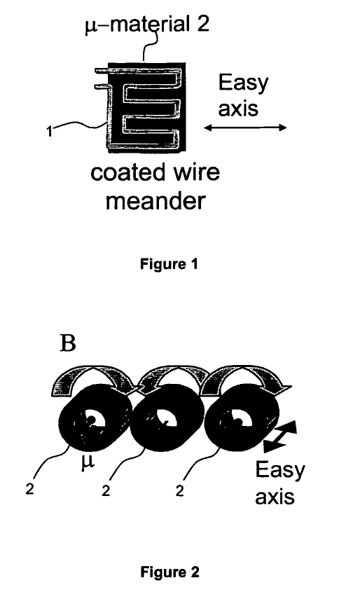

This configuration of conductor embedded in magnetic material that encircles it is especially suitable for inductors where there conductor 1 is straight or comprises a series of straight parallel elements, alternate ends of adjacent elements being connected so as to form a meander as shown in FIG. 1. No advantage would be gained by a spiral configuration of the conductor in most applications, however, since the containment of the magnetic field round each conductor 1 prevents the effect usually encountered with spiral inductors of the mutual inductance between the terms of the spiral increasing the self-conductance of complete spiral. In addition, it is difficult to ensure that the easy axis of the anisotropic magnetic material is always directed along the length of a spiral conductor 1, which is necessary in order to ensure highest possible inductance and magnetic field containment of the device. Moreover, from a practical point of view, a spiral configuration presents a topographical difficulty for making external connection to the inner end of the spiral.

The magnetic material 2 comprises nanometre sized particles of ferromagnetic material. Suitable ferromagnetic materials include Iron, and Iron based alloys with Cobalt, Nickel and other metallic elements.

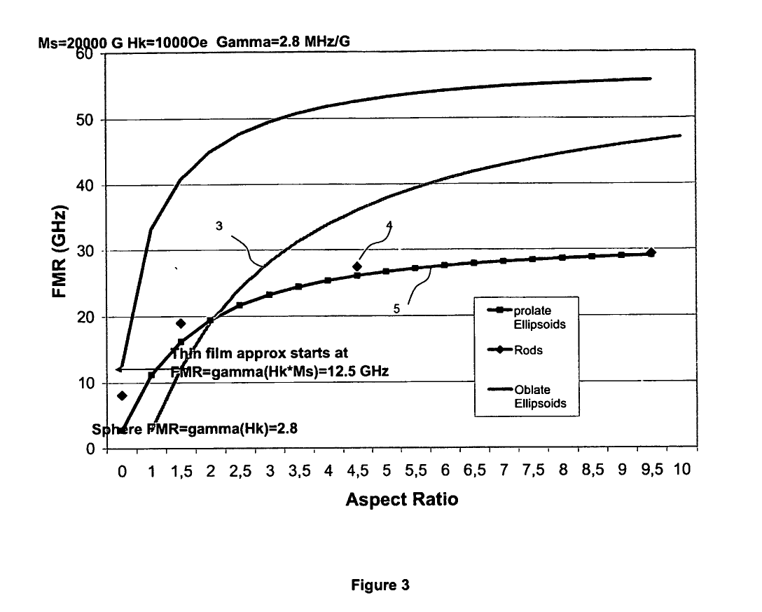

The ferromagnetic resonance frequency of the magnetic material 2 depends on the aspect ratio, of thickness to lateral dimensions, of the individual particles and the volume fraction metal magnetic material in the layer 2, as well as the wire aspect ratio of the conductor and layer. FIG. 3 shows typical values of ferromagnetic resonance frequencies as a function of different shaped particles, including oblate ellipsoids 3, prolate ellipsoids 4 and rods 5.

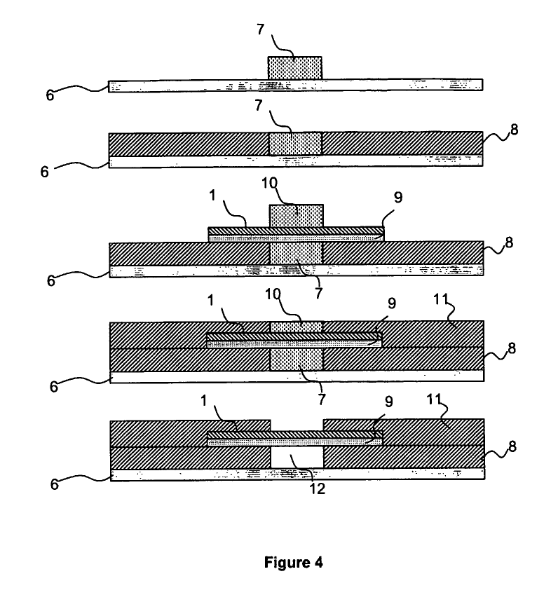

FIG. 4 shows successive steps in a first embodiment of a method of producing the electrical inductor device. A layer of polymer photo resist material is deposited, for example by spinning, onto a substrate 6. The photo resist is exposed to radiation to define a desired pattern for a lower part of the magnetic material 2. The photo resist is then etched to remove undesired portions of the photo resist layer and leave a pattern 7 corresponding to the desired lower portion of magnetic material 2.

In a second step, a layer 8 of Silicon Dioxide (SiO₂) is deposited on the substrate 6 and is planerised to remove the Silicon Dioxide from above the photo resist pattern 7 and form a suitable planar surface for the following steps.

In a third step, metal is deposited on the Silicon Dioxide and over the photo resist 7 using a low temperature process, for example electroplating, so as to preserve the photo resist 7. The deposited metal is masked and etched, for example by plasma etching, to define the desired shape for the conductor 1. A further layer of photo resist polymer is then deposited above and across the conductor 1 and the lower layer of photo resist 7 and etched to produce the desired pattern for an upper layer of the magnetic material 2. In a preferred example of this embodiment of the invention, a Silicon Nitride or seed layer is deposited before the deposition of the metal over the Silicon Dioxide and photo resist 7 so as to form a support membrane for the conductor 1 when the photo resist lower layer 7 is subsequently removed.

It will be appreciated that the views of FIG. 4 are sections along the length of conductor 1 and that the upper and lower photo resist layers 9 and 7 join each other on each side of the conductor 1. It will also be appreciated that, for the sake of clarity, the vertical dimensions of the device shown in the drawings in FIG. 4 and also the subsequent Figures have been exaggerated relative to the length of the conductor 1.

In a fourth step, a further layer 11 of Silicon Dioxide is deposited over the lower layer of Silicon Dioxide 8 and over the ends of the conductor 1 and planerised to remove it from the photo resist 10.

In a fifth step, the polymer photo resist sacrificial layers 10 and 7 are removed by a suitable solvent, leaving the conductor 1 suspended extending across the middle of a cavity 12 in the Silicon Dioxide layers 8 and 11, supported by the membrane 9 if desired.

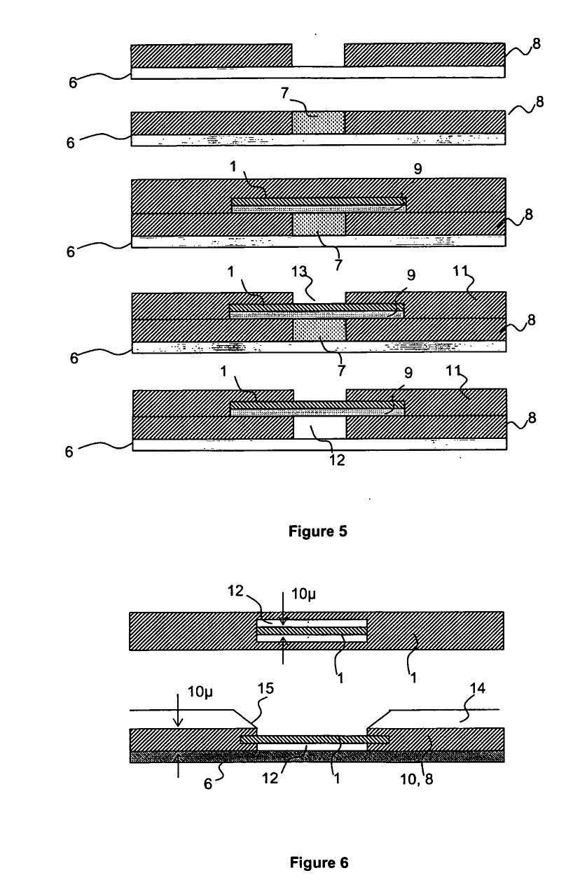

FIG. 5 illustrates another embodiment of a method of making an electrical inductor which is similar to the method of FIG. 4, with the following exceptions.

In the first step the layer 8 of Silicon Dioxide is deposited on the substrate 6. The Silicon Dioxide layer 8 is then etched to produce a desired pattern for the lower layer of magnetic material 2.

In a second step a polymer photo resist material is deposited to fill the cavity left by the etching process of the first step and the polymer layer planerised. The polymer material chosen is insensitive to mask solvent.

In a third step, the conductor 1 is formed on the layer 8, if desired with the membrane support 9 and a layer of Silicon Dioxide 10 formed over the lower Silicon Dioxide layer 8 and the conductor 1 and the polymer 7.

In a fourth step, part of the Silicon Dioxide layer 10 is removed over part of the conductor 1 and over the sacrificial polymer layer 7 to leave a cavity 13 corresponding to the desired upper part of the magnetic material 2, for example using an etching process that preserves the metal of the conductor 1 and the membrane 9.

In a fifth step, the sacrificial polymer layer 7 below the conductor 1 is removed by a suitable solvent.

The upper view of FIG. 6 is a plan view of the element resulting from the processes of FIG. 4 or FIG. 5, showing the conductor 1 extending across the cavity 12 from one end to the other and into the Silicon Dioxide layers 8 and 10. By way of example, the width of the conductor 1 may be of the order of 10 microns, the thickness of the Silicon Dioxide layers 8 and 10 may also be of the order of 10 microns, and the length of the conductor 1 within the cavity 12 is greater than 50 microns. In one example of this embodiment of the process of the invention, a further layer of resin or photo resist material is formed over the Silicon Dioxide layer 10 with an aperture 15 coextensive with the cavity 12, the layer 14 forming a funnel for subsequent introduction of a liquid into the cavity 12.

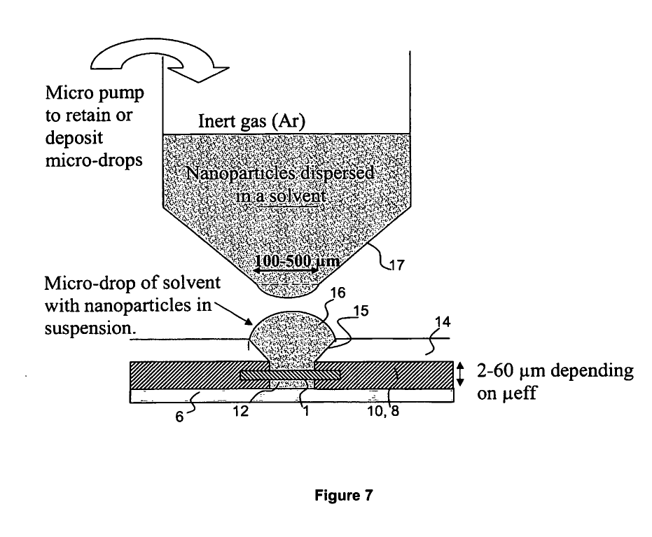

As shown in FIG. 7, a micro drop 16 of liquid is then dropped into the funnel aperture 15 and cavity 12 from a pipette 17. The micro drop 16 comprises the nanoparticles of magnetic material for the magnetic layer 2 dispersed in a liquid dispersant. The suspension is retained within the pipette or released to deposit the micro drop 16 by varying the reduced pressure of inert gas such as Argon above the suspension in the pipette 17.

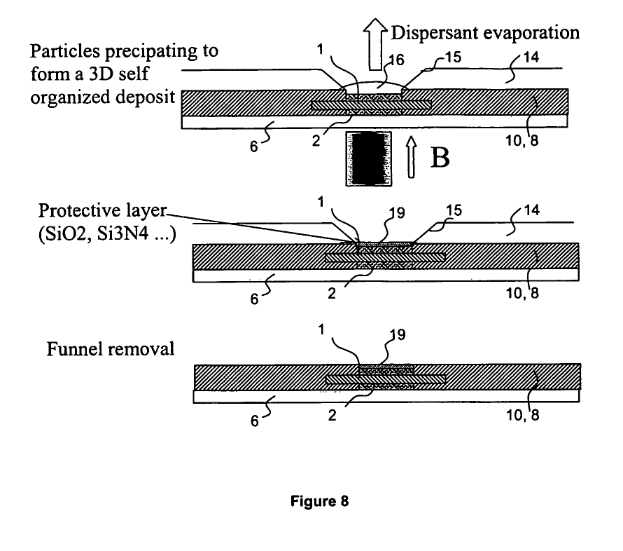

As shown in FIG. 8, the nanoparticles of the suspension are allowed to precipitate around the conductor 1 in the cavity 12 and the liquid dispersant is then evaporated. In this example of the embodiment of the invention, a magnetic field 18 is applied to the cavity 12 as the nanoparticles precipitate and the dispersant evaporates so that the easy access of magnetisation of the magnetic layer 2 is directed along the length of the conductor 1. The magnetic field applied by the magnet 18 is also used in certain embodiments of the process to increase the ordering of the nanoparticles with the magnetic layer 2.

Subsequently, a protective layer 19 of Silicon Dioxide or Silicon Nitride, for example, is deposited over the magnetic layer 2 and lastly the resin layer 14 forming the funnel is removed using a suitable solvent.

In yet another embodiment of the present invention, instead of forming a layer of material 7 below the conductor 1 and subsequently removing it to define the cavity 12 for receiving the magnetic material at the same time below the conductor 1 as above it, as in the process of FIG. 5, a drop of the magnetic material suspension liquid is deposited in the cavity in the Silicon Dioxide layer 8 before deposition of the conductor 1 and the nanoparticles precipitated and the dispersant evaporated to form the lower half of the magnetic material 2. The magnetic material is then protected by a suitable layer such as the membrane layer 9 and the conductor 1 is deposited over the lower layer of magnetic material. The process then proceeds with the formation of the upper part 13 of the cavity and deposition of the upper part of the magnetic material 2, as in the process of FIGS. 5 and 6.

1. A method of producing an electrical circuit element comprising an elongate electrical conductor encircled by magnetic material extending along at least a part of said conductor, the method comprising:
forming at least a first sacrificial layer above and across said conductor;
removing at least part of said first sacrificial layer to leave a space above and across said conductor;
introducing a fluid comprising magnetic nanoparticles dispersed in a liquid dispersant into said space, and
removing said dispersant is removed leaving said magnetic nanoparticles densely packed in said space as at least part of said magnetic material.

2. A method of producing an electrical circuit element as claimed in claim 1, including forming a support layer with a cavity, forming a layer of said magnetic material in said cavity, forming said electrical conductor over said layer of said magnetic material, and forming said first sacrificial layer overlapping said electrical conductor and said layer of said magnetic material.

3. A method of producing an electrical circuit element comprising an elongate electrical conductor encircled by magnetic material extending along at least a part of said conductor, the method comprising:
forming first and second sacrificial layers across said conductor respectively above and below the conductor,
removing at least parts of said sacrificial layers to leave a space encircling said conductor;
introducing a fluid comprising magnetic nanoparticles dispersed in a liquid dispersant into said space, and
removing said dispersant leaving said magnetic nanoparticles densely packed in said space as at least part of said magnetic material.

4. A method of producing an electrical circuit element as claimed in claim 3, including forming a support layer with a cavity, forming said second sacrificial layer in said cavity, forming said electrical conductor over said second sacrificial layer, and forming said first sacrificial layer overlapping said electrical conductor and said second sacrificial layer.

5. A method of producing an electrical circuit element as claimed in claim 3, wherein said support layer comprises electrically insulating material, and said conductor is deposited over said second sacrificial layer and at least part of said layer of insulating material.

6. A method of producing an electrical circuit element as claimed in claim 5, wherein said first sacrificial layer is surrounded by a further layer of insulating material formed over the first said layer of insulating material.

7. A method of producing an electrical circuit element as claimed in claim 1, wherein said sacrificial layer or layers comprise an organic material.

8. A method of producing an electrical circuit element as claimed in claim 1, wherein said sacrificial layer or layers comprise a photo-resist material, and producing said sacrificial layer or layers includes forming a layer or layers of said photo-resist material, exposing said photo-resist material in a pattern defining the geometry of said sacrificial layers and selectively removing photo-resist material, and removing said parts of said sacrificial layers comprises dissolving them in a solvent.

9. A method of producing an electrical circuit element as claimed in claim 1, wherein a further layer of sacrificial material is formed above said conductor with at least one aperture corresponding to said space to contain said fluid before removal of said dispersant.

10. A method of producing an electrical circuit element as claimed in claim 1, and comprising forming a protective layer over said magnetic material (2).

11. A method of producing an electrical circuit element as claimed in claim 1, wherein said magnetic nanoparticles are ferromagnetic.

12. A method of producing an electrical circuit element as claimed in claim 1, wherein said magnetic material presents an easy axis of magnetisation extending along said conductor.

13. A method of producing an electrical circuit element as claimed in claim 1, wherein removing said dispersant comprises evaporating it.

14. A method of producing an electrical circuit element as claimed in claim 1, and comprising applying a magnetic field to said magnetic material while said dispersant is being removed.

15. An electrical circuit element produced by a method as claimed in claim 1.

16. A meander-type inductive element comprising:
a plurality of juxtaposed substantially parallel electrical circuit elements as claimed in claim 15 and at least one electrical interconnection between adjacent ends of the electrical conductors of respective ones of said juxtaposed electrical circuit elements.
